(19) United States
(12) Patent Application Publication
(10) Pub. No.: US 2025/0364314 A1
(43) Pub. Date: Nov. 27, 2025

(54) METHOD OF FORMING SEMICONDUCTOR-ON-INSULATOR (SOI) SUBSTRATE

(71) Applicant: TAIWAN SEMICONDUCTOR MANUFACTURING COMPANY LTD., HSINCHU (TW)

(72) Inventors: YUNG-LUNG LIN, TAICHUNG CITY (TW); SHENG-CHAU CHEN, TAINAN CITY (TW); CHIA-SHIUNG TSAI, HSIN-CHU (TW)

(21) Appl. No.: 18/674,958

(22) Filed: May 27, 2024

(51) Int. Cl. H01L 21/762; H01L 21/02; H01L 21/304; H01L 21/66

(52) U.S. Cl. CPC H01L 21/76251; H01L 21/02381; H01L 21/02532; H01L 21/02579; H01L 21/02598; H01L 21/304; H01L 22/26; H01L 21/02274

(57) ABSTRACT

Methods of forming a silicon-on-insulator (SOI) substrate are provided. The methods include: forming an insulator layer on a first substrate; forming a semiconductor layer on a second substrate; bonding the semiconductor layer to the insulator layer; reducing a thickness of the second substrate; performing an etching operation to remove an entirety of the second substrate and a top portion of the semiconductor layer; and performing a polishing operation to reduce a thickness of the semiconductor layer, thereby forming a device layer having a target thickness on the insulator layer, wherein a real-time measurement is conducted during the reducing of the thickness of the semiconductor layer to monitor the thickness of the semiconductor layer while the polishing operation is being performed.

### BACKGROUND

Semiconductor-on-insulator (SOI) technology is becoming increasingly important in semiconductor processing. An SOI substrate structure typically contains a buried insulator layer, which functions to electrically isolate a top silicon layer from a base semiconductor substrate. Having non-equal indices of refraction of the buried insulator layer and the top silicon layer facilitates formation of optical waveguides that confine light entering the top silicon layer. Therefore, electrical devices, such as transistors, and optical devices, such as waveguides, grating couplers, optical modulators, and electrical devices, can be formed in the SOI substrate to reduce a footprint of a photonic integrated circuit.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, dimensions of the various features may be arbitrarily increased or reduced for clarity of discussion.

FIG. 1 is a flowchart of a method of manufacturing a semiconductor-on-insulator (SOI) substrate, in accordance with some embodiments of the present disclosure.

FIGS. 2 to 10 are cross-sectional views of intermediate stages of the method of manufacturing an SOI substrate, in accordance with some embodiments of the present disclosure.

FIG. 11 is a cross-sectional view of a grinding apparatus that holds a bonded structure, in accordance with some embodiments of the present disclosure.

FIG. 12 is a top view of a bonded structure, a chuck table, a level-adjusting member, and a grinding wheel, in accordance with some embodiments of the present disclosure.

FIG. 13A is a diagram illustrating a centrally-recessed shape substrate, in accordance with some embodiments of the present disclosure.

FIG. 13B is a diagram illustrating a centrally-projecting shape substrate, in accordance with some embodiments of the present disclosure.

FIG. 14 is a diagram illustrating an inclination of a chuck table used to polish a centrally-recessed shape substrate, in accordance with some embodiments of the present disclosure.

FIG. 15 is a diagram illustrating an inclination of a chuck table used to polish a centrally-projecting shape substrate, in accordance with some embodiments of the present disclosure.

FIG. 16 is a perspective view of a polishing apparatus before a stacked structure is polished, in accordance with some embodiments of the present disclosure.

FIG. 17 is a perspective view of the polishing apparatus during polishing of a stacked structure, in accordance with some embodiments of the present disclosure.

FIG. 18 is a cross-sectional view of a polishing head for holding a stacked structure, in accordance with some embodiments of the present disclosure.

FIG. 19 is a bottom view of the polishing head illustrated in FIG. 18, in accordance with some embodiments of the present disclosure.

FIG. 20 is a plan view of a polishing pad, a first sensing module, a second sensing module, and a stacked structure during operation, in accordance with some embodiments of the present disclosure.

FIG. 21 is a circuit block diagram of the polishing apparatus, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for a purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence, order, or importance unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” or “about” generally mean within a value or range (e.g., within 10%, 5%, 1%, or 0.5% of a given value or range) that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

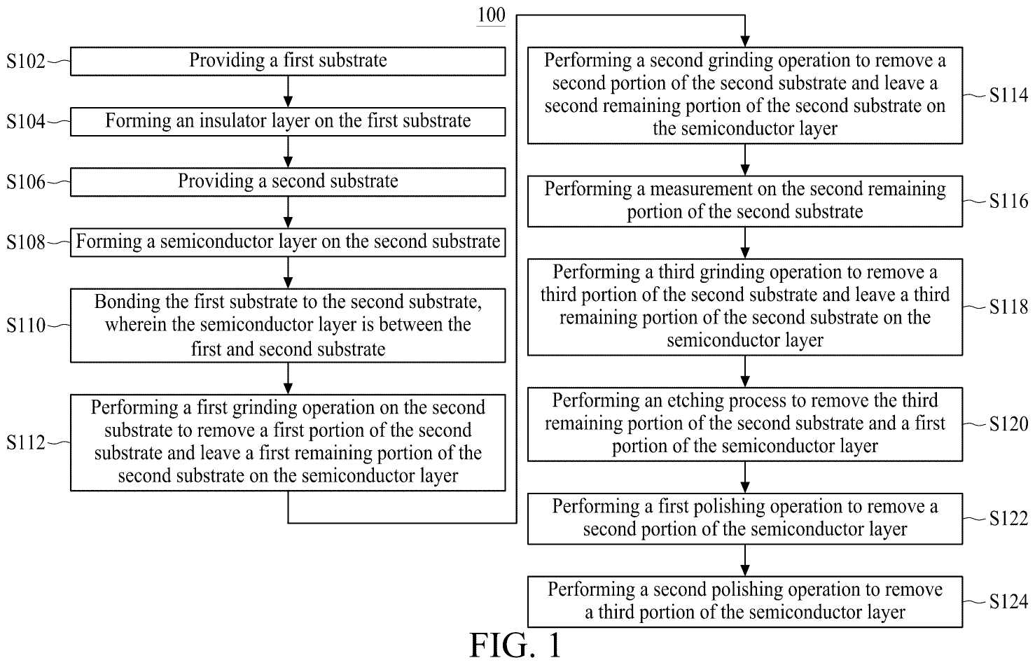

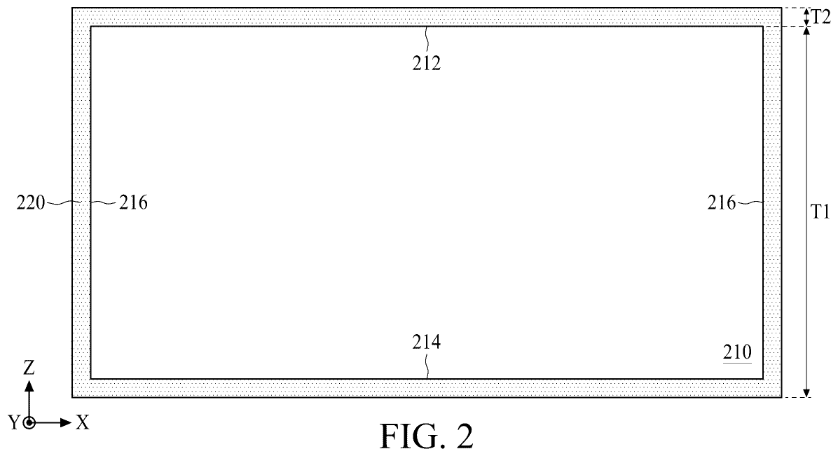

FIG. 1 is a flowchart of a method 100 of manufacturing a semiconductor-on-insulator (SOI) substrate, in accordance with some embodiments of the present disclosure. FIGS. 2 to 10 are cross-sectional views of intermediate stages of the method 100 of manufacturing the SOI substrate, in accordance with some embodiments of the present disclosure. In the following description, the manufacturing stages shown in FIGS. 2 to 10 are discussed with reference to the process steps shown in FIG. 1. It should be understood that additional steps can be provided before, during, and after the steps shown in FIG. 1, and some of the steps described below can be replaced or eliminated, for additional embodiments of the method 100. The order of the steps may be changed.

Referring to FIG. 2, a first substrate 210 is provided in accordance with step S102 in FIG. 1. The first substrate 210 may include elementary semiconductor materials, compound semiconductor materials, and/or alloy semiconductor materials. The elementary semiconductor materials may include, for example, silicon or germanium. Examples of the compound semiconductor materials may be, but are not limited to, silicon carbide (SiC), gallium arsenic (GeAs), gallium phosphide (GaP), indium phosphide (InP), indium arsenide (InAs), and/or indium antimonide (InSb). Examples of the alloy semiconductor materials may be, but are not limited to, silicon germanium (SiGe), gallium arsenide phosphide (GaAsP), aluminum indium arsenide (AlInAs), aluminum gallium arsenide (AlGaAs), gallium indium arsenide phosphide (GaInAs), gallium indium phosphide (GaInP), and/or gallium indium arsenide phosphide (GaInAsP). In some embodiments, the first substrate 210 includes monocrystalline silicon. The first substrate 210 may be a silicon wafer. In some embodiments, the first substrate 210 has a thickness T1 between about 500 μm and about 1000 μm, such as between about 720 μm and about 800 μm. The thickness T1 may be, for example, about 775 μm.

Still referring to FIG. 2, an insulator layer 220 is formed to encircle the first substrate 210 in accordance with step S104 in FIG. 1. In some embodiments, the insulator layer 220 covers a first surface 212, a second surface 214, and side surfaces 216 of the first substrate 210, wherein the second surface 214 is opposite to the first surface 212, and the side surfaces 216 connect the first surface 212 to the second surface 214. In some embodiments, the insulator layer 220 includes a dielectric material, such as an oxide. The insulator layer 220 may be formed by performing a thermal oxidation operation; hence, the insulator layer 220 includes a material provided by the first substrate 210. The insulator layer 220 formed from thermally grown oxide may provide a high-quality semiconductor/dielectric interface of the final structure.

In some embodiments, the insulator layer 220 is disposed on an entirety of an upper surface 212 of the first substrate 210. The insulator layer 220 on the upper surface 212 of the first substrate 210 may include, for example, an oxide (such as silicon oxide), a nitride (such as silicon nitride), an oxynitride (such as silicon oxynitride), or the like. The insulator layer 220 including the oxide, the nitride, or the oxynitride may be formed to cover the upper surface 212 of the first substrate 210 by a chemical vapor deposition (CVD) operation, such as a plasma-enhanced CVD operation or a low-pressure CVD operation.

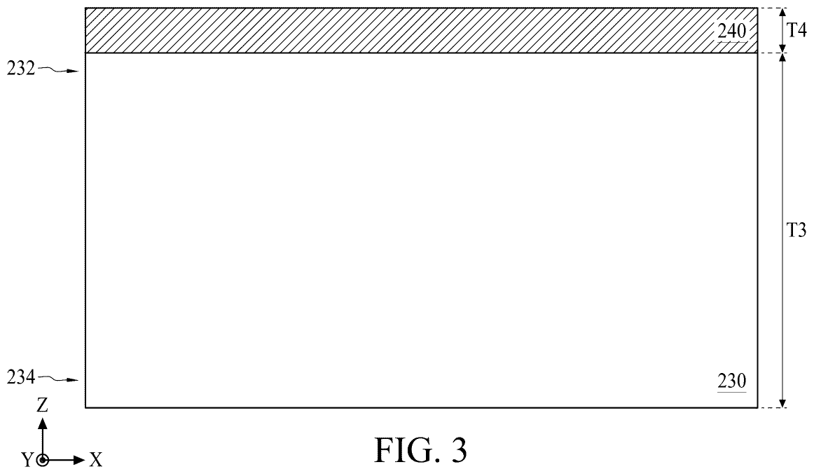

Referring to FIG. 3, a second substrate 230 is provided in accordance with step S106 of FIG. 1. The second substrate 230 includes a silicon-containing material. For example, the second substrate 230 is a silicon wafer. In some embodiments, the second substrate 230 has a p-type conductivity type. The p-type second substrate 230 may be formed by introducing p-type dopants to the second substrate 230. In the silicon containing material, examples of p-type dopants include, but are not limited to, boron, aluminum, gallium, and indium. In some embodiments, the second substrate 230 is doped using ion implantation. In alternative embodiments, the p-type dopants are introduced to the second substrate 230 by an in-situ doping operation that is performed during formation of the second substrate 230. The second substrate 230 has a first doping concentration. In some embodiments, the doping concentration of the p-type dopant that is introduced to the second substrate 230 is, for example, greater than 1×10¹⁵ atoms/cm³. The second substrate 230 may have a thickness T3 substantially equal to the thickness T1. In some embodiments, the thickness T3 is between about 720 μm and about 800 μm. The thickness T3 is, for example, about 775 μm.

Still referring to FIG. 3, a semiconductor layer 240 is formed on the second substrate 230 in accordance with step S108 in FIG. 1. In some embodiments, the semiconductor layer 240 includes a silicon-containing material. The semiconductor layer 240 may be formed on a front side 232 of the second substrate 230. The semiconductor layer 240 has a conductivity type same as that of the second substrate 230, i.e., the semiconductor layer 240 is doped with a p-type dopant. The semiconductor layer 240 has a second dopant concentration greater than the first dopant concentration of the second substrate 230. For example, the second substrate 230 may be or include p+ monocrystalline silicon, and the semiconductor layer 240 may be or include p− monocrystalline silicon. The second doping concentration may be, for example, between 1×10¹⁹ cm³ and 2×10²⁰ cm³.

The semiconductor layer 240 may be formed on the second substrate 230 using molecular beam epitaxy (MBE), vapor phase epitaxy (VPE), or liquid phase epitaxy (LPE). The p-type dopant may be introduced to the semiconductor layer 240 during the epitaxy growth operation that forms the semiconductor layer 240. The semiconductor layer 240 has a thickness T4 greater than a thickness T2 of the insulator layer 220 and less than the thickness T1 of the first substrate 210. The thickness T4 is between about 4 μm and about 6 μm. The thickness T4 of the semiconductor layer 240 is, for example, about 4.6 μm.

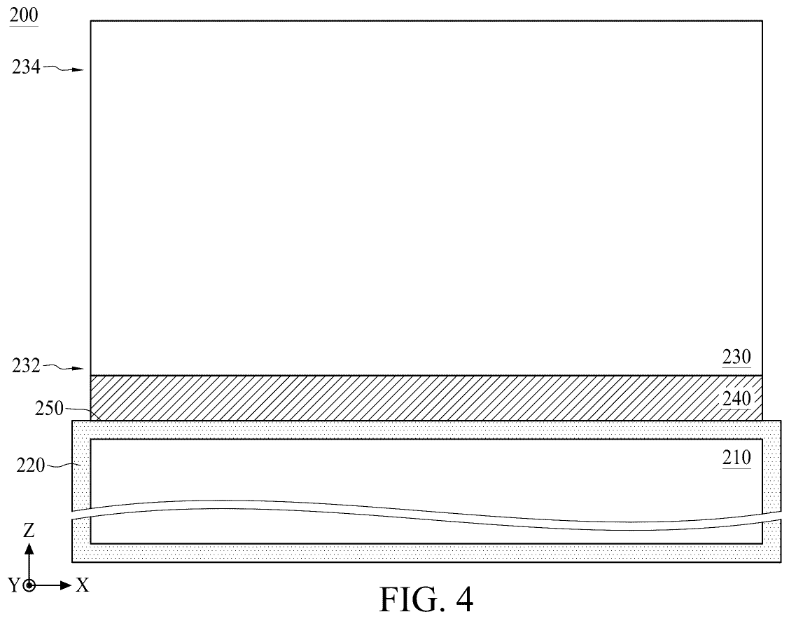

Referring to FIG. 4, the second substrate 230 is bonded to the first substrate 210 in accordance with step S110 in FIG. 1. Accordingly, a bonded structure 200 is formed, wherein the semiconductor layer 240 is between the first substrate 210 and the second substrate 230. The bonding of the first substrate 210 to the second substrate 230 includes flipping the second substrate 230 and the semiconductor layer 240 from an orientation shown in FIG. 3, and placing the flipped second substrate 230 and the semiconductor layer 240 on the insulator layer 220. In some embodiments, an alignment is performed so that the semiconductor layer 240 is aligned with the insulator layer 220. The alignment of the semiconductor layer 240 and the insulator layer 220 is achieved, for example, using optical sensing. After the alignment of the semiconductor layer 240 and the insulator layer 220, the semiconductor layer 240 and the insulator layer 220 are brought into contact, initiating a weaker bond, such as a Van der Waals bond. In some embodiments, heat treatment or pressure treatment is performed to increase bonding strength. As a result, the semiconductor layer 240 is covalent bonded to the insulator layer 220. After the bonding operation, a semiconductor-to-dielectric bonding interface 250 such as a silicon-to-oxide bonding interface may be formed between the insulator layer 220 and the semiconductor layer 240.

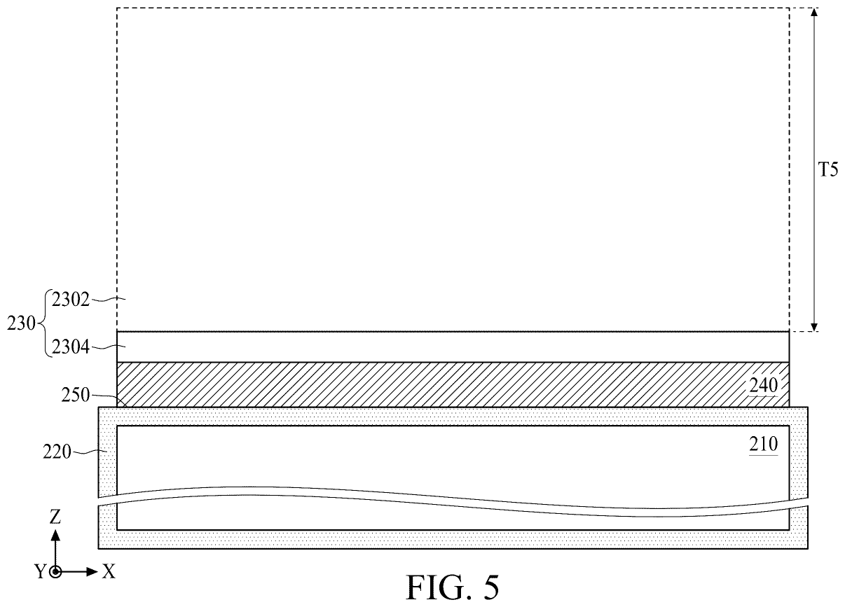

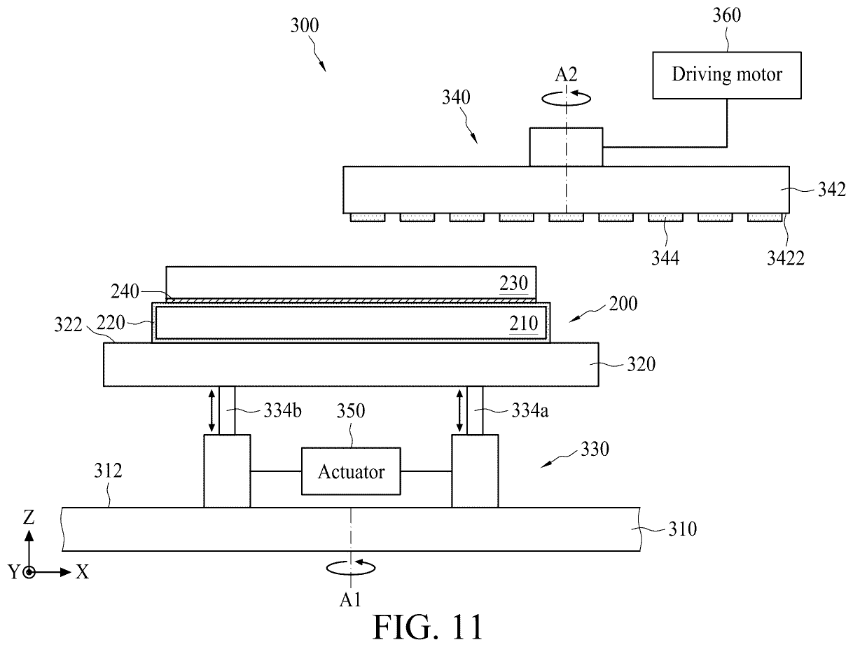

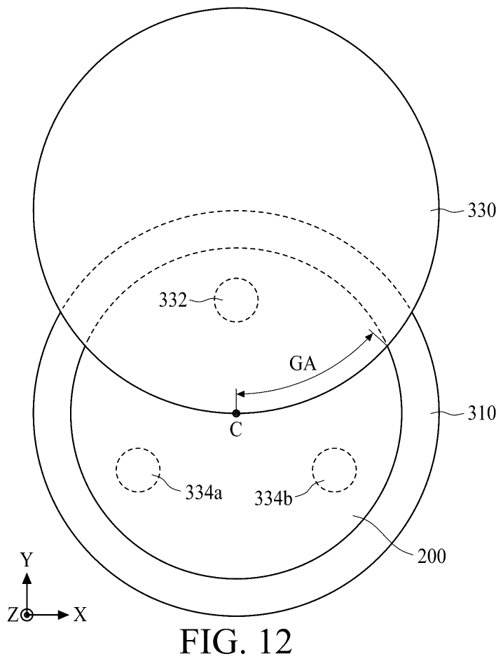

Referring to FIG. 5, a first grinding operation is performed on the second substrate 230 to remove a first portion 2302 of the second substrate 230 in accordance with step S112 in FIG. 1. The second substrate 230 is ground from a rear side 234 opposite to the front side 232, while a first remaining portion 2304 of the second substrate 230 is left on the semiconductor layer 240. In some embodiments, the first grinding operation is carried out to reduce the thickness of the second substrate 230. The first portion 2302 of the second substrate 230, removed during the first grinding operation, has a thickness T5. The thickness T5 may be between about 680 μm and 750 μm. The thickness T5 is, for example, about 695 μm. The first grinding operation may be performed by a grinding apparatus 300, as shown in FIGS. 11 and 12.

FIG. 11 is a cross-sectional view of the grinding apparatus 300 holding the bonded structure 200, in accordance with some embodiments of the present disclosure. Referring to FIGS. 11 and 12, the grinding apparatus 300 is configured to reduce the thickness of the second substrate 230 and may include a base 310, a chuck table 320, a level-adjusting member 330, and a grinding wheel 340. The base 310 has a supporting surface 312 and is rotated about an axis A1 during operation. In some embodiments, the axis A1 extends parallel to the Z-direction and passes through a center of the base 310. The bonded structure 200 is placed on the chuck table 320. In some embodiments, the bonded structure 200 is held on a holding surface 322 of the chuck table 320 under suction, wherein the second substrate 230 is oriented upward (i.e., the second substrate 230 is disposed farther from the chuck table 310 than the first substrate 210).

The level-adjusting member 330 is configured to control an inclination angle of the chuck table 320. FIG. 12 is a top view illustrating an arrangement relationship among the bonded structure 200, the chuck table 320, the level-adjusting member 330, and the grinding wheel 340, in accordance with some embodiments of the present disclosure. Referring to FIGS. 11 and 12, the level-adjusting member 330 may include a fixed shaft 332 and at least two movable shafts, i.e., a first movable shaft 334a and a second movable shaft 334b, each of which is connected to both the base 310 and the chuck table 320. In some embodiments, the fixed shaft 332, the first movable shaft 334a, and the second movable shaft 334b each has an axial direction in the Z-direction, and all three shafts are disposed respectively at the three vertexes of a regular triangle having a center at a center of the chuck table 320. During operation of the grinding apparatus 300, the fixed shaft 332 remains stationary (i.e., the fixed shaft 332 is not movable), while the movable shafts 334a and 334b may move in the vertical direction (i.e., the Z-direction) on the base 310. Due to the control by the level-adjusting member 330, the chuck table 320 is inclined relative to the supporting surface 312 of the base 310 by upward and downward movements of the first and second movable shafts 334a and 334b. In some embodiments, the first and second movable shafts 334a and 334b are electrically driven by one or more actuators 350.

The grinding wheel 340 is configured to grind the second substrate 230, which is held on the chuck table 320. The grinding wheel 340 may include a wheel base 342, and a plurality of grinding stones 344 mounted to a lower surface 3422 of the wheel base 342. Each of the grinding stones 344 includes abrasive grains of diamond glued together by a vitrified bond or the like. In some embodiments, the grinding wheel 340 is positioned to partially overlap the second substrate 230 from a top-view perspective. For example, a central axis C of the bonded structure 200 passes through an outer circumferential portion or a peripheral portion of the wheel base 342 from a top-view perspective.

During operation, the wheel base 342 is driven to rotate about an axis A2. The grinding wheel 340 may be rotated at a rotational speed different from a rotational speed of the chuck table 320. The rotating grinding wheel 340 is then lowered a predetermined distance in the Z-direction at a first feed rate. In some embodiments, the axis A2 is inclined with respect to the axis A1 of the base 310 of the grinding apparatus 300. The grinding wheel 340 grinds the bonded structure 200 in a grinding area GA extending from the outer circumferential portion of the bonded structure 200 to the center C thereof on an orbit. A back side of the second substrate 230 is ground until the first portion 2302 of the second substrate 230 shown in FIG. 5 is removed. The first feed rate is between about 3 μm/s and about 8 μm/s. The first feed rate is, for example, about 5 μm/s. In some embodiments, the first and second movable shafts 334a and 334b are held stationary during the first grinding operation. Accordingly, the chuck table 320 may hold the bonded structure 200 in a substantially horizontal posture and rotate the bonded structure 200 about the axis A1 during operation.

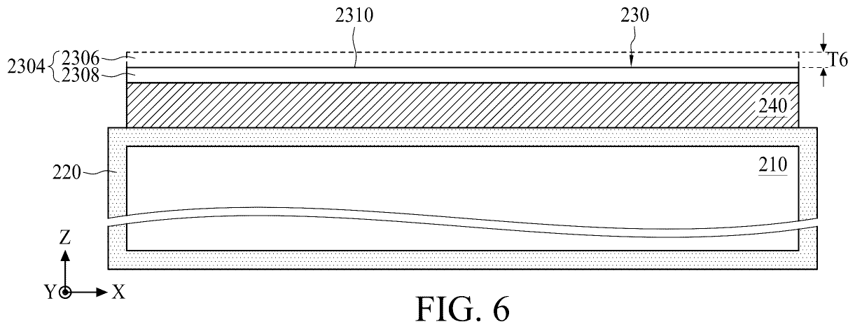

Referring to FIG. 6, a second grinding operation is performed to remove a second portion 2306 of the second substrate 230 in accordance with step S114 in FIG. 1. Accordingly, a second remaining portion 2308 of the second substrate 230 remains on the semiconductor layer 240. The second grinding operation is carried out to reduce a thickness of the second substrate 230. In some embodiments, the second portion 2306 of the second substrate 230 has a thickness T6. The thickness T6 is, for example, between about 20 μm and about 40 μm. The second grinding operation may be performing using the grinding apparatus 300 shown in FIG. 11. The first and second grinding operations may be performed using different grinding apparatus.

During the second grinding operation, the rotating grinding wheel 340 is lowered a predetermined distance in the Z-direction at a second feed rate. In some embodiments, the second feed rate is less than the first feed rate. The second feed rate may be between 0.2 μm/s and about 0.8 m/s. The second feed rate is, for example, about 0.6 μm/s. The rotational speed of the chuck table 320 during the second grinding operation may be the same as or different from the rotational speed of the chuck table 320 during the first grinding operation. The rotational speed of the grinding wheel 340 during the second grinding operation may be the same as or different from the rotational speed of the grinding wheel 340 during the first grinding operation. In some embodiments, the first and second movable shafts 334a and 334b are held stationary during the first grinding operation.

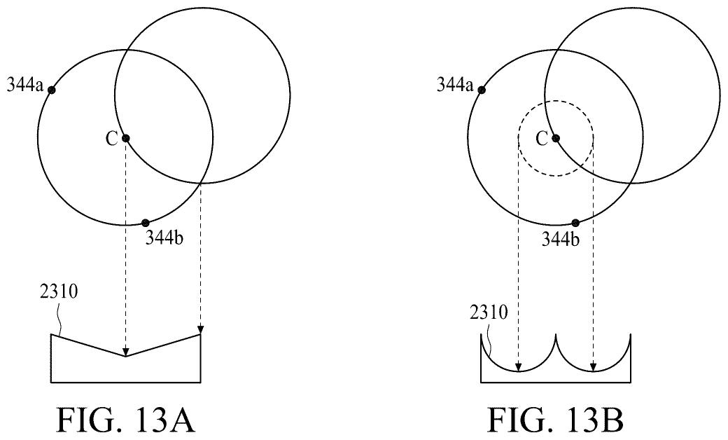

After the second grinding operation, a central portion of the second remaining portion 2308 of the second substrate 230 may be thinner or thicker than a peripheral portion of the second remaining portion 2308 of the second substrate 230 due to uneven wear of the grinding stones 344. A concave profile, shown in FIG. 13A, is formed when the central portion of the second remaining portion 2308 of the second substrate 230 is thinner than the peripheral portion thereof. A W-shaped profile, shown in FIG. 13B, is formed when the central portion and the peripheral portion of the second remaining portion 2308 of the second substrate 230 are thicker than portions between the central and peripheral portions thereof. The non-uniform thickness of the second remaining portion 2308 of the second substrate 230 may be detrimental for subsequent operations (such as the thinning of the semiconductor layer 240 to a target thickness with a target planarity). Therefore, after the second grinding operation, a measurement operation (step S116) is carried out to determine a topography of an upper surface 2310 of the second remaining portion 2308 of the second substrate 230.

The measurement may be performed on a surface topography of the upper surface 2310 of the second remaining portion 2308. The measurement may be conducted using a non-contact topography measurement tool (not shown). For example, the measurement is conduct using an optical measurement tool. In some embodiments, the optical measurement tool is configured to measure the surface topography of the second remaining portion 2308 of the second substrate 230. The optical measurement tool may be designed to have a reflective mechanism. For example, an optical beam emitted from a beam source is applied to the upper surface 2310 of the second remaining portion 2308 of the second substrate 230, and a reflected optical beam is received by a receiver, thereby measuring the surface topography of the upper surface 2310. In some embodiments, the measurement and the second grinding operation are performed in-situ. The measured surface topography is provided to the actuator 350 to control the movements of the first and second movable shafts 334a and 334b during a subsequent third grinding operation.

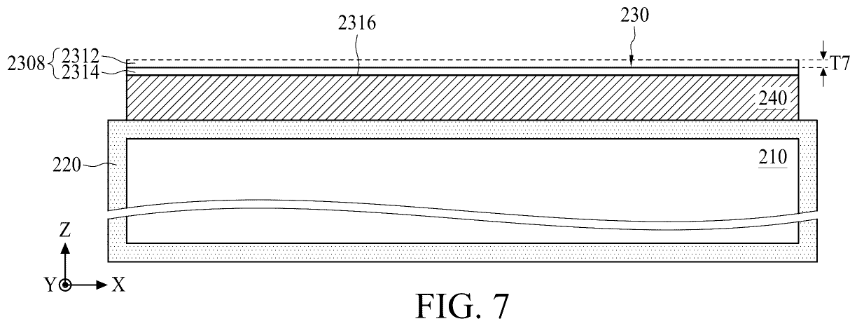

Referring to FIG. 7, the third grinding operation is performed to remove a third portion 2312 of the second substrate 230 in accordance with step S118 in FIG. 1. Accordingly, a third remaining portion 2314 of the second substrate 230 is left on the semiconductor layer 240. The third grinding operation is carried out to further reduce the thickness of the second substrate 230 and to provide a substantially planar surface of the third remaining portion 2314. In some embodiments, the third portion 2312 of the second substrate 230 has a thickness T7 less than the thickness T6 shown in FIG. 6. The thickness T7 may be, for example, between about 10 μm and about 20 μm. In some embodiments, a sum of the thickness of the second portion 2306 of the second substrate 230 removed during the second grinding operation (shown in FIG. 6) and the thickness of the third portion 2312 of the second substrate 230 removed during the third grinding operation (shown in FIG. 7) is about 60 μm. The third grinding operation is performing using the grinding apparatus 300 shown in FIG. 11. In some embodiments, the second and third grinding operations are performed using the same grinding tool, and the surface topography of the second remaining portion 2308 of the second substrate 230 is determined by an in-situ measurement in the grinding apparatus. Therefore, all of second substrate 230 enters the grinding tool 400 performing the second grinding operation is measured before the third grinding operation, and the non-uniform surface caused by the uneven wear of the grinding stones 344 is planarized during the third grinding operation.

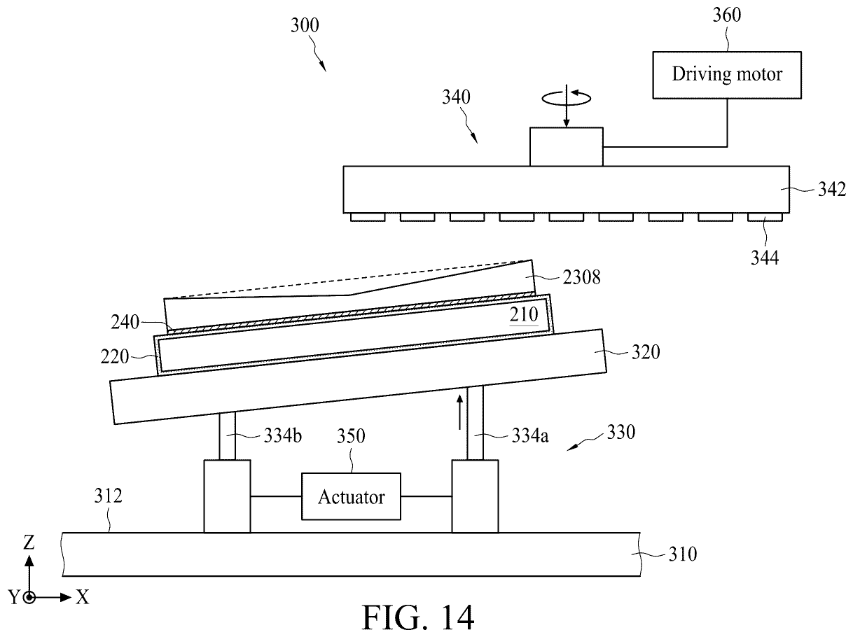

During the third grinding operation, at least one of the first and second movable shafts 334a and 334b is driven firstly by the actuator 350 to raise or lower according to the measured surface topography, and then the chuck table 320 is driven to rotate. For example, when the upper surface 2310 of the second remaining portion 2308 of the second substrate 230 has the concave profile, as shown in FIG. 14, the first movable shaft 334a is raised (and the second movable shaft 334b may be lowered); hence, the chuck table 320 is inclined relative to the supporting surface 312 of the base 310 to cause the material at the peripheral portion of the second substrate 230 to be grinded away greater than the central portion of the second substrate 230. As shown in FIG. 14, the peripheral portion of the second substrate 230 comes into contact with the grinding stones 344 before the central portion of the second substrate 230 is ground. Therefore, the grinding starts from the peripheral portion and gradually proceeds to the central portion. As a result, the planar surface of the third remaining portion 2314 is achieved.

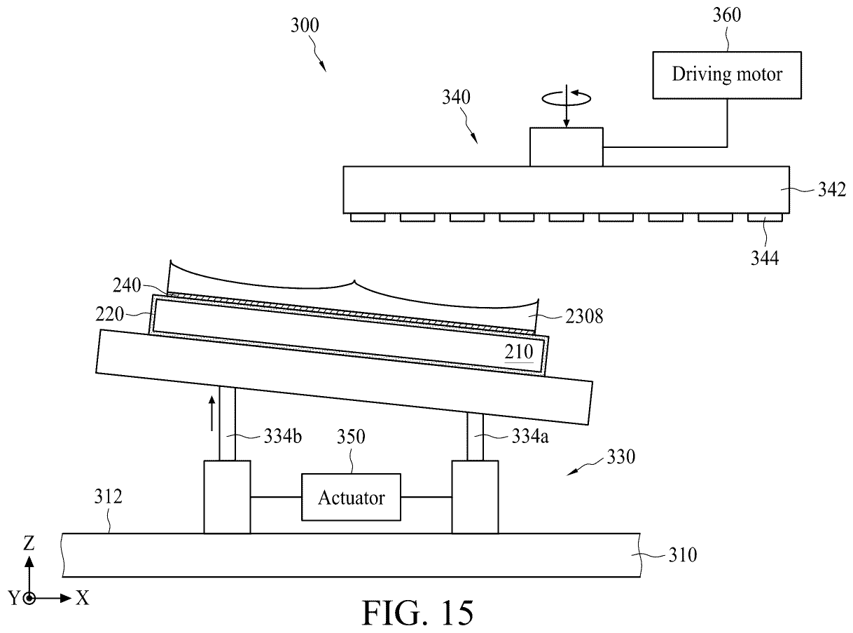

For another example, when the upper surface 2310 of the second remaining portion 2308 of the second substrate 230 has the W-shaped profile as shown in FIG. 15, the second movable shaft 334b is raised (and the first movable shaft 334a may be lowered); hence, the chuck table 320 is inclined is inclined relative to the supporting surface 312 of the base 310 to cause the material at the central portion of the second substrate 230 to be grinded away greater than the peripheral portion of the second substrate 230. As shown in FIG. 15, the central portion of the second substrate 230 comes into contact with the grinding stones 344 before the peripheral portion of the second substrate 230 is ground. Therefore, the grinding starts at the central portion of the second substrate 230 and gradually proceeds to the peripheral portion. As a result, the surface of the third remaining portion 2314 with better planarity is achieved. The third grinding operation may be performed at a third feed rate less than the second feed rate of the second grinding operation. The third feed rate is between about 0.1 μm/s and about 0.5 μm/s. The third feed rate is, for example, about 0.2 μm/s.

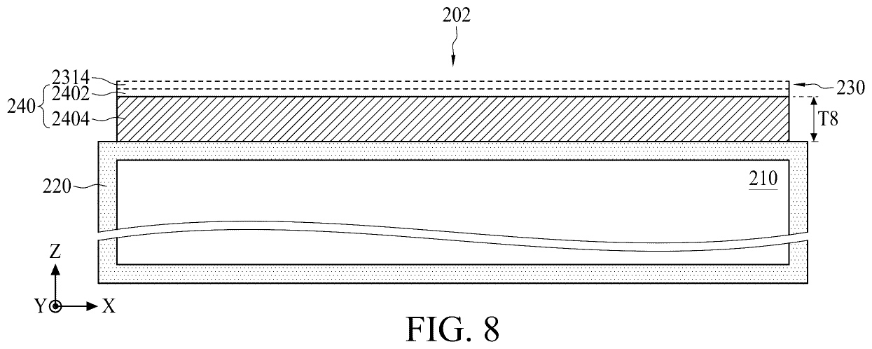

Referring to FIG. 8, an etching operation is performed to remove the third remaining portion 2314 of the second substrate 230 and a first portion 2402 of the semiconductor layer 240 in accordance with step S120 in FIG. 1. Accordingly, a first remaining portion 2404 of the semiconductor layer 240 remains on the insulator layer 220, and a stacked structure 202 is formed. In some embodiments, the second substrate 230 and the semiconductor layer 240 are sequentially etched using a same etchant. The etchant may include HNA (hydrofluoric acid, nitric acid, and acetic acid). In some embodiments, after the etching process, the first remaining portion 2404 of the semiconductor layer 240 has a thickness T8 between about 4.0 μm and about 4.4 μm. The thickness T8 is, for example, about 4.3 μm.

The first to third grinding operations remove portions of the second substrate 230 much more rapidly than the etching operation. However, mechanical stresses may be introduced into the semiconductor layer 240 during the first and third grinding operations, resulting in a lattice strain in the semiconductor layer 240. The presence of such lattice strain in the semiconductor layer 240 may be undesirable for a number of reasons. For example, the presence of lattice strain in a layer of semiconductor material may result in formation of cracks in the semiconductor layer 240. Such cracks may adversely affect a reliability of a final product. Accordingly, the feed rates of the first to third grinding operations are controlled to reduce mechanical stresses introduced into the semiconductor layer 240. The etching operation is used to reduce or eliminate mechanical stress applied to the semiconductor layer 240. By performing the etching operation to remove the third remaining portion 2314 of the second substrate 230, a lattice strain in the semiconductor layer 240 underlying the second substrate 230 may be effectively reduced compared to an alternative approach in which the first to third grinding operations are performed.

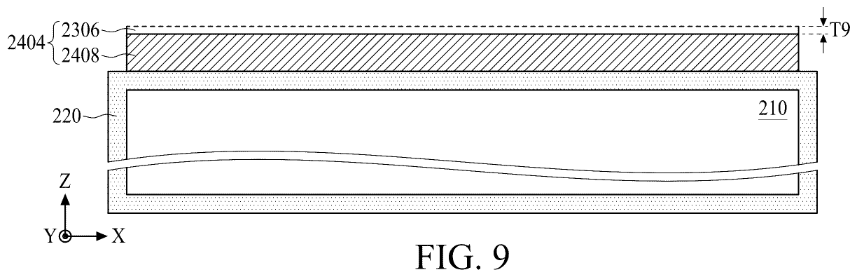

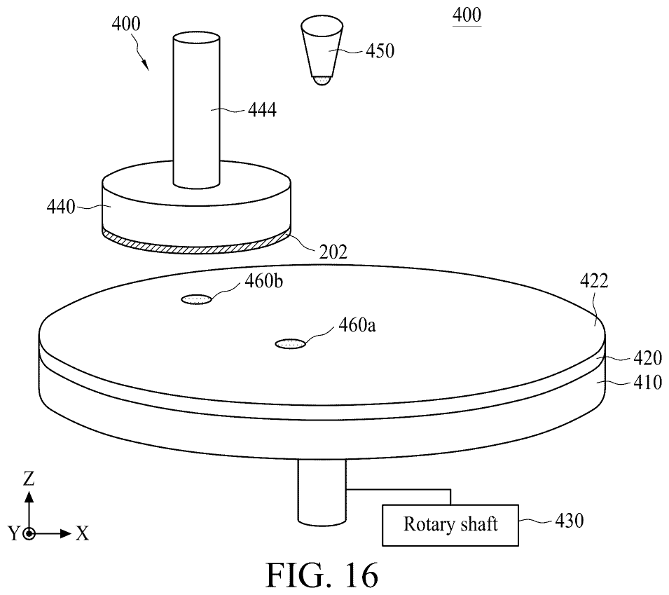

Referring to FIG. 9, a first polishing operation is performed to remove a second portion 2306 of the semiconductor layer 240 in accordance with step S122 in FIG. 1. Accordingly, a second remaining portion 2408 of the semiconductor layer 240 is left on the insulator layer 220. The first polishing operation is performed to remove material from the semiconductor layer 240 to reduce a thickness of the semiconductor layer 240. In some embodiments, the second portion 2306 of the semiconductor layer 240, which is removed during the first polishing operation, has a thickness T9 between about 1 μm and about 3 μm. The first polishing operation may be performed by a polishing apparatus 400, as shown in FIG. 16.

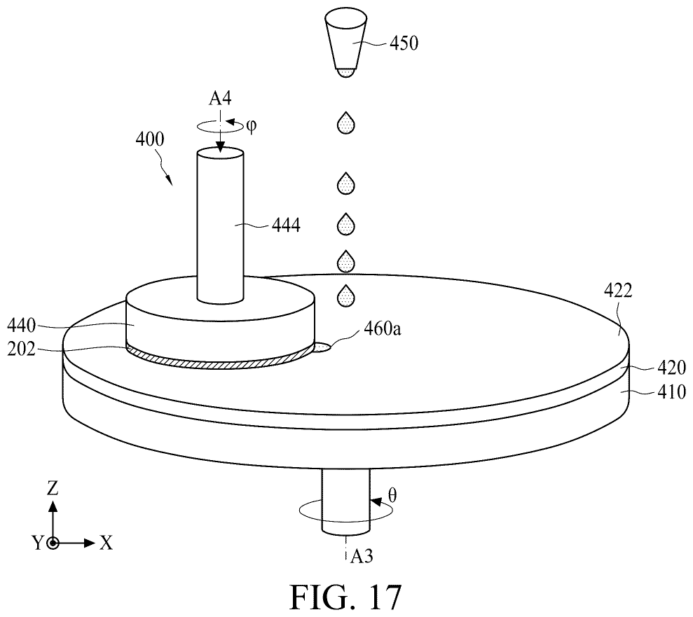

FIG. 16 is a perspective view of a polishing apparatus 400 before the stacked structure 202 is polished, in accordance with some embodiments of the present disclosure, and FIG. 17 is a perspective view of the polishing apparatus 400 during the polishing of the stacked structure 202, in accordance with some embodiments of the present disclosure. Referring to FIGS. 16 and 17, in some embodiments, the polishing apparatus 400 includes a platen 410, a polishing pad 420, a rotary shaft 430, a polishing head 440, a slurry supplier 450, and a pair of sensing modules, i.e., a first sensing module 460a and a second sensing module 460b. The polishing pad 420 is placed on an upper surface of the platen 410, which is rotated by the rotary shaft 430 about an axis A3 during operation. The rotary shaft 430 may be configured to rotate the platen 410 at a first angular velocity θ.

The polishing head 440 holds the stacked structure 202 and presses the stacked structure 202 against an upper surface 422 of the polishing pad 420 during the first polishing operation. In some embodiments, during the first polishing operation, the polishing head 440 is lowered a predetermined distance in the Z-direction at a third feed rate. The third feed rate is about 6000 angstroms/min.

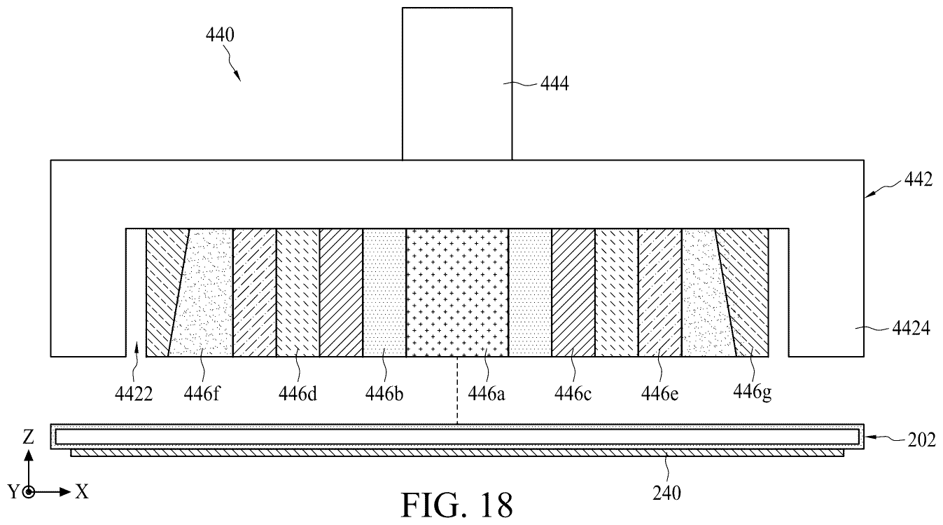

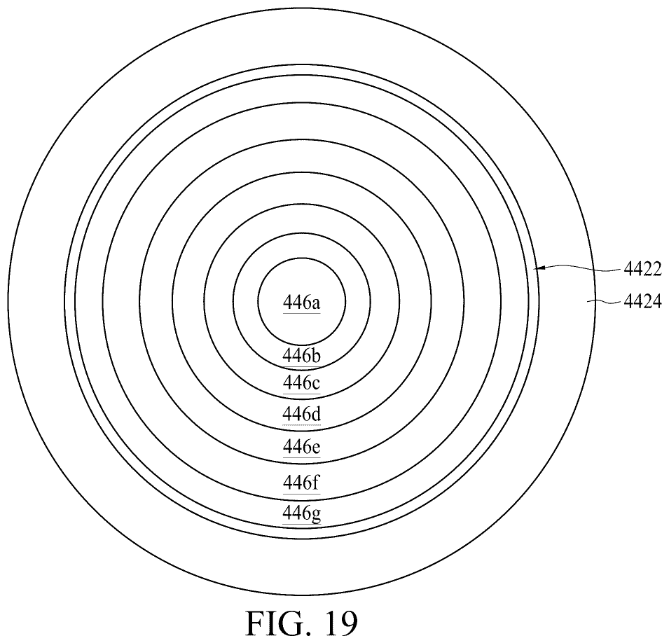

FIG. 18 is a cross-sectional view of a polishing head 440 for holding the stacked structure 202, in accordance with some embodiments of the present disclosure. FIG. 19 is a bottom view of the polishing head 440 shown in FIG. 18, in accordance with some embodiments of the present disclosure. Referring to FIGS. 18 and 19, in some embodiments, the polishing head 440 includes a frame 442, a driving shaft 444, and a plurality of pressing members 446a, 446b, 446c, 446d, 446c, 446f, and 446g. The frame 442 may include an inverted U-shaped cross-section that defines a recess 4422 to receive the pressing members 446a to 446g and includes a projection portion 4424 for holding the stacked structure 202. The projection portion 4424 may have a ring shape from a bottom-view perspective. In some embodiments, the frame 442 has a diameter substantially equal to a diameter of the stacked substrate 202, so that the frame 442 holds the stacked structure 202 at the peripheral portion of the stacked structure 202. The stacked structure 202 may be held on the lower surface of the projection portion 4424 under suction, wherein the insulator layer 220 is in contact with the projection portion 4424 and the semiconductor layer 240 is oriented downward (i.e., the semiconductor layer 240 is disposed farther from the frame 442 than the first substrate 210).

The driving shaft 444 is coupled to the top of the frame 442 for rotating the frame 442 at a second angular velocity φ about an axis A4. The first angular velocity θ may be different from the second angular velocity φ. In some embodiments, the pressing member 446a is a cylinder-shaped structure, and the pressing members 446b to 446g are circular rings arranged in a concentric fashion. Each of the pressing members 446a to 446g may exert a pressure on a backside of the stacked structure 202 during operation, such that a surface of the semiconductor layer 240 is pressed and polished to meet thickness and surface profile uniformity targets. Regarding arrangement of the pressing members, although an example is shown in FIGS. 18 and 19 wherein seven pressing members 446a to 446g are arranged in concentric fashion, the number of the pressing members does not necessarily need to be seven and they are not limited to arrangement in a concentric fashion.

Referring back to FIG. 17, the slurry supplier 450 applies a slurry onto the polishing pad 420 during polishing. In some embodiments, the slurry is dispensed in droplets onto the upper surface 422 of the polishing pad 420 to effectuate a chemical mechanical removal of material from the first remaining portion 2404 of the semiconductor layer 240. The combined action of a downward force of the polishing head 440, the respective rotations of the platen 410 and the polishing head 440, and the chemical and mechanical effects of the slurry combine to polish the lower surface of the semiconductor layer 240 to a first target thickness.

Referring back to FIG. 16, the polishing pad 420 may have a diameter greater than the diameter of the polishing head 440. The first and second sensing modules 460a and 460b are embedded in the polishing pad 420 and configured for in-situ measurement of the stacked structure 202 during the first polishing operation. The first and second sensing modules 460a and 460b may be configured to collect information for determining physical properties at different zones of the stacked structure 202. For example, the first and second sensing modules 460a and 460b are used to detect thickness information of the stacked structure 202 being polished. The information from the first and second sensing modules 460a and 460b can be used to better control operations of the polishing apparatus 400 (e.g., the pressing members 446a to 446g of the polishing head 440) to provide improved performance.

A real-time measurement of the stacked structure 202 may be conducted by using the first and second sensing modules 460a and 460b. In some embodiments, the first sensing module 460a is used to collect information describing thickness at a peripheral zone (also referred to as a peripheral thickness) of the semiconductor layer 240, and the second sensing module 460b is used to collect information describing a thickness at a central zone (also referred to as a central thickness) of the semiconductor layer 240. The central thickness and the peripheral thickness of the stacked structure 202 are determined by an in-situ measurement in the polishing apparatus 400. In some embodiments, an upper surface of the first sensing module 460a is flush with the upper surface 422 of the polishing pad 420, and an upper surface of the second sensing module 460b is flush with the upper surface 422 of the polishing pad 420 to facilitate better operation of the polishing apparatus 400. When the upper surfaces of the first and second sensing modules 460a and 460b are lower than the upper surface 422 of the polishing pad 420, the slurry may accumulate on the upper surfaces of the first and second sensing modules 460a and 460b, which may adversely affect the measurement result of the stacked structure 202. The upper surfaces of the first and second sensing modules 460a and 460b being higher than the upper surface of the polishing pad 420 is adverse for the polishing operation and will damage the stacked structure 202.

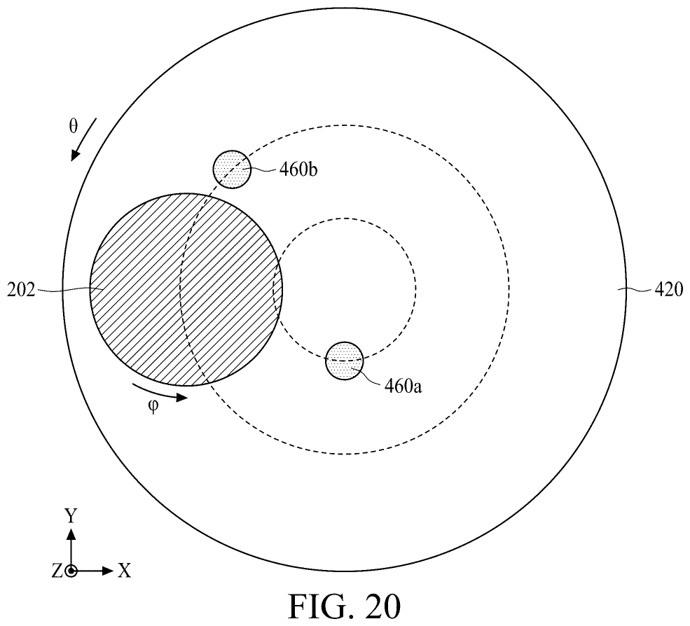

FIG. 20 is a plan view illustrating the stacked structure 202, the polishing pad 420, the first sensing module 460a, and the second sensing module 460b during operation, in accordance with some embodiments of the present disclosure. Referring to FIGS. 17 and 20, during polishing, the platen 410 is rotated about the axis A3 while the polishing head 440, holding the stacked structure 202, is rotated about the axis A4 at independent rates of rotation. The stacked structure 202 is then brought into contact with the polishing pad 420. The first and second sensing modules 460a and 460b may begin to operate when the stacked structure 202 contacts the polishing pad 420. In some embodiments, the first and second sensing modules 460a and 460b monitor the thicknesses of the stacked structure 202 during the polishing of the stacked structure 202.

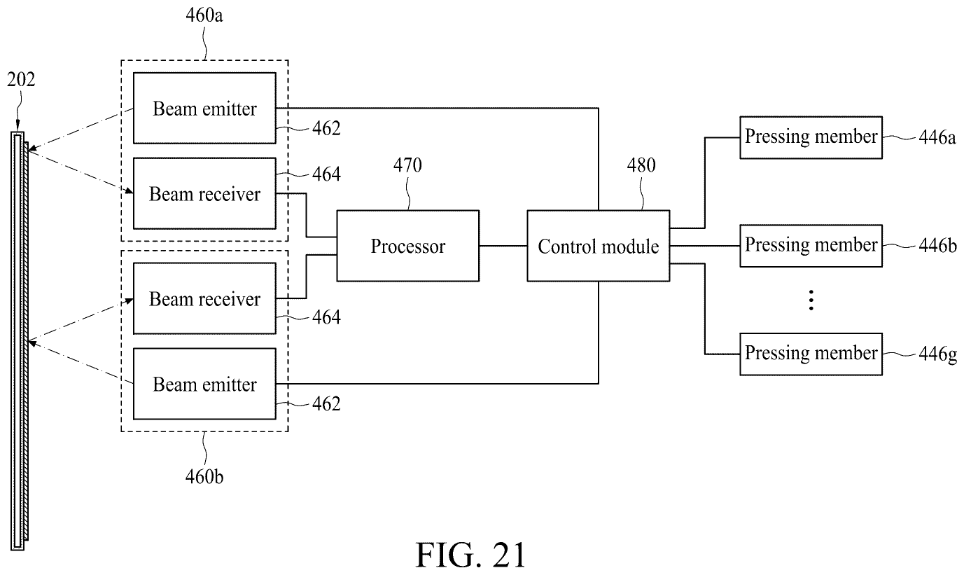

FIG. 21 is a circuit block diagram of the polishing apparatus 400, in accordance with some embodiments of the present disclosure. Referring to FIG. 21, in some embodiments, each of the first and second sensing modules 460a and 460b may include an optical emitter 462 and an optical receiver 464. In some embodiments, the optical emitter 462 is configured to provide light. The light may be reflected when the stacked structure 202 rotated by the polishing head 440 overlaps the first sensing module 460a or the second sensing module 460b placed on the polishing pad 420, which is rotated by the rotary shaft 430. In some embodiments, the optical receiver 464 is configured to receive light reflected from the stacked structure 202 and provide diffracted light having a linear dispersion of wavelengths. In some embodiments, the optical receiver 464 is part of a spectrally dispersive device (such as a monochromator, spectrometer, optical spectrum analyzer, etc.). In other embodiments, the optical receiver 464 is the spectrally dispersive device. The optical receiver 464 may be further configured to convert the diffracted light to corresponding electrical signals. The optical receivers 464 may provide the electrical signals to a processor 470.

In some embodiments, the processor 470 is configured to determine the central thickness and the peripheral thickness of the semiconductor layer 240 by analyzing the electrical signals in real time. The processor 470 may be further configured to calculate a first difference between the peripheral thickness and the target thickness, thereby determining an amount of the material of the semiconductor layer 240 to be removed at the peripheral zone of the stacked structure 202. In addition, the processor 470 may be further configured to calculate a second difference between the central thickness and the target thickness in real time, thereby determining an amount of the material of the semiconductor layer 240 to be removed at the central zone of the stacked structure 202. In some embodiments, the processor 470 is further configured to compare, in real time, the first difference to the second difference, generate a comparison result, and provide the comparison result to a control module 480.

The control module 480 is configured to control the operation of the pressing members 446a to 446g in response to the comparison result in real time, so as to polish the semiconductor layer 240 to the desired planarity. For example, at a beginning of the first grinding operation (e.g., before the control module 480 receives the comparison result), the control module 480 is configured to control the pressing members 446a to 446g to apply substantially equal pressing forces to the stacked structure 202. As such, the stacked structure 202 is polished by pressing force that is consistent over its entire radius. When the comparison result indicates that the first difference is equal to the second difference (i.e., the peripheral thickness is equal to the central thickness), the control module 480 may be configured to control the pressing members 446a to 446g to apply a substantially consistent pressing force to the stacked structure 202.

On the other hand, when the comparison result indicates that the first difference is different from the second difference (i.e., the peripheral thickness is different from the central thickness), the control module 480 is configured to control the pressing members 446a to 446g to apply different pressing forces to the stacked structure 202. In other words, one or more pressing forces applied to the semiconductor layer 220 will be adjusted. As such, the stacked structure 202 is polished by an uneven pressing force over its entire radius.

For example, when the comparison result indicates that the first difference is greater than the second difference, one or more pressing members proximal to the peripheral region, such as the pressing members 446e to 446g, are controlled to apply greater pressing force to corresponding zones of the stacked structure 202. Alternatively, one or more pressing members proximal to the central region, such as the pressing members 446a to 446d, are controlled to apply less pressing force to corresponding zones of the stacked structure 202.

For another example, when the comparison result indicates that the first difference is less than the second difference, one or more pressing members proximal to the central region, such as the pressing members 446a to 446d, are controlled to apply greater pressing force to the corresponding zones of the stacked structure 202. Alternatively, one or more pressing members proximal to the peripheral region, such as the pressing members 446e to 446g, are controlled to apply less pressing force to the corresponding zones of the stacked structure 202. In some embodiments, the first polishing operation is terminated when the periphery thickness and the central thickness are equal to the first target thickness.

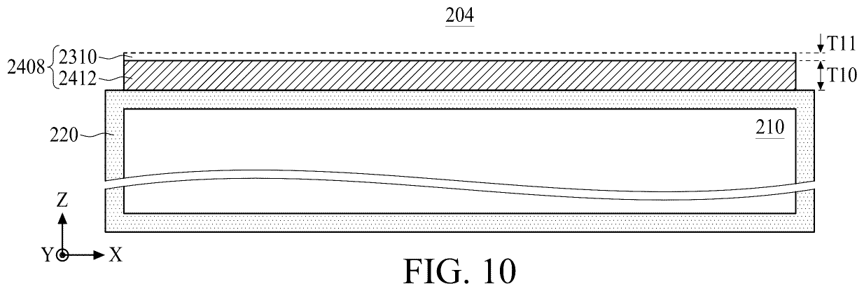

Referring to FIG. 10, a second polishing operation is performed to remove a third portion 2310 of the second remaining portion 2308 of the semiconductor layer 240 in accordance with step S124 in FIG. 1. Accordingly, a third remaining portion 2412 of the semiconductor layer 240 is left on the insulator layer 220, and therefore, an SOI substrate 204 is completely formed. The third remaining portion 2412 of the semiconductor layer 240 serves as a device layer or a surface layer of the SOI substrate 204, where optical waveguides or transistors are formed. The second polishing operation may be performed to remove material from the semiconductor layer 240 to further reduce a thickness of the semiconductor layer 240. In some embodiments, the second polishing operation is terminated when the periphery thickness and the central thickness are equal to a second target thickness T10. In some embodiments, the second target thickness T10 is about 30,200 angstroms. The third portion 2310 of the semiconductor layer 240 may have a thickness T11 between about 30 angstroms and about 1000 angstroms. In some embodiments, after the second polishing operation, a cleaning operation is performed to clean and remove polishing residue and slurry on the third remaining portion 2412 of the semiconductor layer 240. The third remaining portion 2412 of the semiconductor layer 240 may be cleaned using pure water (DIW, i.e., deionized water).

The second polishing operation may be performed by the polishing apparatus 400 shown in FIG. 16. In some embodiments, the first and second polishing operations are performed in-situ. A real-time measurement of a peripheral thickness and a central thickness of the stacked structure 202 may be conducted during the second polishing operation to provide better planarity of a device layer of the SOI substrate 204. During the second polishing operation, the polishing head 440 is lowered a predetermined distance in the Z-direction at a fourth feed rate. In some embodiments, the fourth feed rate is between about 200 angstroms/min and about 300 angstroms/min.

In accordance with some embodiments of the present disclosure, a method of forming a silicon-on-insulator substrate includes: forming an insulator layer on a first substrate; forming a semiconductor layer on a second substrate; bonding the semiconductor layer to the insulator layer; reducing a thickness of the second substrate; performing an etching operation to remove an entirety of the second substrate and a top portion of the semiconductor layer; and performing a polishing operation to reduce a thickness of the semiconductor layer, thereby forming a device layer having a target thickness on the insulator layer, wherein a real-time measurement is conducted during the polishing of the semiconductor layer to monitor the thickness of the semiconductor layer.

In accordance with some embodiments of the present disclosure, a method of forming an SOI substrate includes: depositing an insulator layer on a first substrate; forming a semiconductor layer on a second substrate; bonding the semiconductor layer to the insulator layer; removing the second substrate; reducing a thickness of the semiconductor layer to a target thickness by applying a plurality of pressing forces to a plurality of zones of the semiconductor layer; measuring, in real time, a plurality of layer thicknesses in the plurality zones of the semiconductor layer; and, in response to the measuring, adjusting, in real time, at least one of the plurality of pressing forces applied to a corresponding zone of the semiconductor layer.

In accordance with some embodiments of the present disclosure, a method of forming an SOI substrate includes: depositing an insulator layer on a first substrate; forming a semiconductor layer on a second substrate; bonding the semiconductor layer to the insulator layer; removing the second substrate; and reducing a thickness of the semiconductor layer to a target thickness. The reducing of the thickness of the semiconductor layer includes: performing a polishing operation on the semiconductor layer by applying an even pressing force from a polishing head to the semiconductor layer; measuring, in real time, a first thickness in a first zone and a second thickness in a second zone of the semiconductor layer; calculating, in real time, a first difference between the first thickness and the target thickness; calculating, in real time, a second difference between the second thickness and the target thickness; and, in response to a determination that the first difference is greater than the second difference, applying, in real time, an uneven pressing force to the semiconductor layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an insulator layer on a first substrate;
forming a semiconductor layer on a second substrate;
bonding the semiconductor layer to the insulator layer;
reducing a thickness of the second substrate;
performing an etching operation to remove an entirety of the second substrate and a first portion of the semiconductor layer; and
performing a polishing operation to reduce a thickness of the semiconductor layer, thereby forming a device layer having a target thickness on the insulator layer,
wherein a real-time measurement is conducted during the polishing of the semiconductor layer to monitor the thickness of the semiconductor layer.

2. The method of claim 1, wherein the reducing of the thickness of the second substrate comprises:
performing a grinding operation on the second substrate to remove a first thickness of the second substrate such that a first remaining portion is disposed on the semiconductor layer;
performing a measurement to determine a topography of an upper surface of the first remaining portion of the second substrate; and
performing a second grinding operation on the first remaining portion of the second substrate to remove a second thickness of the second substrate, thereby forming a second remaining portion having a planar surface,
wherein the first thickness is greater than the second thickness.

3. The method of claim 2, wherein:
the grinding operation is performed at a first feed rate,
the second grinding operation is performed at a second feed rate less than the first feed rate.

4. The method of claim 1, wherein the reducing of the thickness of the semiconductor layer comprises:
performing the polishing operation on the semiconductor layer by applying an even pressing force from a polishing head to the semiconductor layer;
measuring, in real time, a fifth thickness in a first zone and a sixth thickness in a second zone of the semiconductor layer;
calculating, in real time, a first difference between the fifth thickness and the target thickness;
calculating, in real time, a second difference between the sixth thickness and the target thickness; and
in response to a determination that the first difference is greater than the second difference, applying, in real time, an uneven pressing force to the semiconductor layer.

5. The method of claim 4, wherein the first zone of the semiconductor layer is polished at a first pressing force, and the second zone of the semiconductor layer is polished at a second pressing force less than the first pressing force.

6. The method of claim 4, wherein the polishing operation is terminated when the fifth and sixth thicknesses are equal to the target thickness.

7. The method of claim 1, wherein the etching operation is performed using a hydrofluoric/nitric/acetic (HNA) etchant.

8. The method of claim 1, wherein the semiconductor layer and the second substrate comprise a same semiconductor material and a same doping type, and the semiconductor layer and the second substrate have different doping concentrations.

9. The method of claim 1, wherein the second substrate comprises P+ monocrystalline silicon, and the semiconductor layer comprises P− monocrystalline silicon.

10. The method of claim 1, wherein the insulator layer completely surrounds the first substrate.

11. A method of forming a semiconductor-on-insulator (SOI) substrate, comprising:
depositing an insulator layer on a first substrate;
forming a semiconductor layer on a second substrate;
bonding the semiconductor layer to the insulator layer;
removing the second substrate;
reducing a thickness of the semiconductor layer to a target thickness by applying a plurality of pressing forces to a plurality of zones of the semiconductor layer;
measuring, in real time, a plurality of layer thicknesses in the plurality of zones of the semiconductor layer; and
in response to the measurement, adjusting, in real time, at least one of the plurality of pressing forces applied to the corresponding zone of the semiconductor layer.

12. The method of claim 11, wherein the removal of the second substrate comprises:
performing a first grinding operation at a first feed rate to reduce a thickness of the second substrate from a first thickness to a second thickness;
performing a second grinding operation at a second feed rate to reduce the thickness of the second substrate from the second thickness to a third thickness, wherein the first feed rate is greater than the second feed rate;
performing a third grinding operation at a third feed rate to reduce the thickness of the second substrate from the third thickness to a fourth thickness, wherein the third feed rate is less than the second feed rate; and
performing an etching operation to remove an entirety of the second substrate.

13. The method of claim 12, wherein the removal of the second substrate further comprises:
determining a surface topography of the second substrate between the second and third grinding operations.

14. The method of claim 12, wherein a top portion of the semiconductor layer is removed during the etching operation.

15. The method of claim 11, wherein the semiconductor layer and the second substrate comprise a same semiconductor material and a same doping type, and the semiconductor layer and the second substrate have different doping concentrations.

16. A method of forming a semiconductor-on-insulator (SOI) substrate, comprising:
depositing an insulator layer on a first substrate;
forming a semiconductor layer on a second substrate;
bonding the semiconductor layer to the insulator layer;
removing the second substrate; and
reducing a thickness of the semiconductor layer to a target thickness,
wherein the reducing of the thickness of the semiconductor layer comprises:
performing a polishing operation on the semiconductor layer by applying an even pressing force to the semiconductor layer;
measuring, in real time, a first thickness in a first zone and a second thickness in a second zone of the semiconductor layer;
calculating, in real time, a first difference between the first thickness and the target thickness;
calculating, in real time, a second difference between the second thickness and the target thickness;
comparing, in real time, the first difference to the second difference; and
in response to determining that the first difference is different from the second difference, applying, in real time, an uneven pressing force to the semiconductor layer.

17. The method of claim 16, wherein the first zone of the semiconductor layer is polished at a first pressing force, and the second zone of the semiconductor layer is polished at a second pressing force less than the first pressing force.

18. The method of claim 17, wherein the reducing of the thickness of the semiconductor layer further comprises performing an etching operation to reduce the thickness of the semiconductor layer before the performing of the polishing operation.

19. The method of claim 18, wherein a first portion of the semiconductor layer removed using the etching operation has a third thickness, a second portion of the semiconductor layer removed using the polishing operation has a fourth thickness, and the third thickness is less than the fourth thickness.

20. The method of claim 17, wherein the reducing of the thickness of the semiconductor layer further comprises performing a cleaning operation after the first thickness and the second thickness are equal to the target thickness.
